(19) United States
(12) Patent Application Publication
(10) Pub. No.: US 2022/0412729 A1
(43) Pub. Date: Dec. 29, 2022

(54) DOT PATTERN PROJECTOR FOR USE IN THREE-DIMENSIONAL DISTANCE MEASUREMENT SYSTEM

(71) Applicant: HIMAX TECHNOLOGIES LIMITED, Tainan City (TW)

(72) Inventor: Ming-Shu Hsiao, Tainan City (TW)

(73) Assignee: HIMAX TECHNOLOGIES LIMITED, Tainan City (TW)

(21) Appl. No.: 17/358,011

(22) Filed: Jun. 25, 2021

(51) Int. Cl. G01B 11/25; H04N 13/254

(52) U.S. Cl. CPC G01B 11/254; H04N 13/254

(57) ABSTRACT

A dot pattern projector includes a light source array, a lens and a diffracting unit. The light source array includes a plurality of light sources that emit light beams. The lens is configured to collimate the light beams. The diffracting unit is configured to diffract the collimated light beams thereby to project an illumination pattern, wherein the illumination pattern is formed by overlapping multiple dot patterns that are projected by different light sources or interlacing multiple dot patterns that are projected by different light sources.

### BACKGROUND OF THE INVENTION

### 1. Field of the Invention

The present invention relates to three-dimensional optical distance measurement, and more particularly to, a dot pattern projector for use in a three-dimensional optical distance measurement system.

### 2. Description of the Prior Art

Typically, three-dimensional optical distance measurement based on time-of-flight (ToF) technology relies on a flood illuminator in conjunction with an imaging sensor to provide distance measurements of an object or shape. However, a distance of projection of the flood illuminator is pretty short due to its weak optical energy.

In view of this, there is a need to provide a pattern projector which can provide high-power illumination pattern as well as considerable distance of projection.

### SUMMARY OF THE INVENTION

With this in mind, it is one object of the present invention to provide a regular dot pattern projector for use in a three-dimensional optical distance measurement system. Embodiments of the present invention may rely on a light source array in conjunction with a lens as well as a diffracting unit to produce illumination pattern with regularly distributed dots. Embodiments of the present invention allow dot patterns produced by different light sources of the light source array to be overlapped or interlaced thereby to form the illumination pattern. According to various embodiments, the diffracting unit may be implemented with a microlens array (MLA) or a diffractive optical element (DOE). Due to flexibility provided by different interfacing types of embodiments of the present invention, parameters of components of the dot pattern projector will have wide ranges of adjustment. This significantly improves the flexibility of the design and the fabrication of the dot pattern projector.

According to one embodiment, a dot pattern projector is provided. The dot pattern projector comprises: a light source array, a lens and a diffracting unit. The light source array includes a plurality of light sources that emit light beams. The lens is configured to collimate the light beams. The diffracting unit is configured to diffract the collimated light beams thereby to project an illumination pattern. The illumination pattern is formed by overlapping multiple dot patterns that are projected by different light sources or interlacing multiple dot patterns that are projected by the light sources.

According to one embodiment, an optical distance measurement system is provided. The optical distance measurement system comprises: a flood illuminator, a dot pattern projector and an image capturing device. The flood illuminator includes at least one light source and a diffuser. The flood illuminator is configured to project a first illumination pattern. The dot pattern projector is configured to project a second illumination pattern. The dot pattern projector comprises: a light source array, a lens and a diffracting unit. The light source array includes a plurality of light sources that emit light beams. The lens is configured to collimate the light beams. The diffracting unit is configured to diffract the collimated light beams thereby to project an illumination pattern, wherein the illumination pattern are formed by overlapping multiple dot patterns that are projected by different light sources or interlacing multiple dot patterns that are projected by different light sources. The image capturing device is configured to capture images of light pattern reflected from an object.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a schematic diagram of an optical distance measurement system according to one embodiment of the present invention.

FIG. 2 illustrates an implementation of a dot pattern projector and a flood illuminator according to one embodiment of the present invention.

FIG. 3 illustrates a detailed schematic diagram of a dot pattern projector according to one embodiment of the present invention.

FIGS. 4A-4E illustrate how an illumination pattern is formed by overlapping dot patterns according to one embodiment of the present invention.

FIGS. 5A-5E illustrate how an illumination pattern is formed by interlacing dot patterns according to one embodiment of the present invention.

FIGS. 6A-6B illustrate how an arrangement of a light sources array affects a dot distribution of an illumination pattern according to different embodiments of the present invention.

FIG. 7 illustrate how arrangements of source arrays and microlens arrays, and an interlacing type affects dot distributions of the illumination pattern according to embodiments of the present invention.

### DETAILED DESCRIPTION

In the following description, numerous specific details are set forth in order to provide a thorough understanding of the present embodiments. It will be apparent, however, to one having ordinary skill in the art that the specific detail need not be employed to practice the present embodiments. In other instances, well-known materials or methods have not been described in detail in order to avoid obscuring the present embodiments.

Reference throughout this specification to “one embodiment” or “an embodiment” means that a particular feature, structure or characteristic described in connection with the embodiment or example is included in at least one embodiment of the present embodiments. Thus, appearances of the phrases “in one embodiment” or “in an embodiment” in various places throughout this specification are not necessarily all referring to the same embodiment. Furthermore, the particular features, structures or characteristics may be combined in any suitable combinations and/or sub-combinations in one or more embodiments.

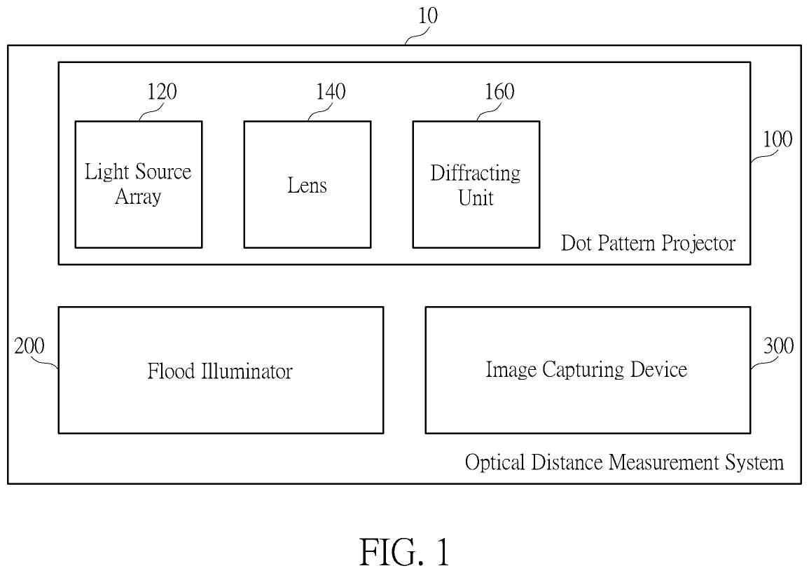

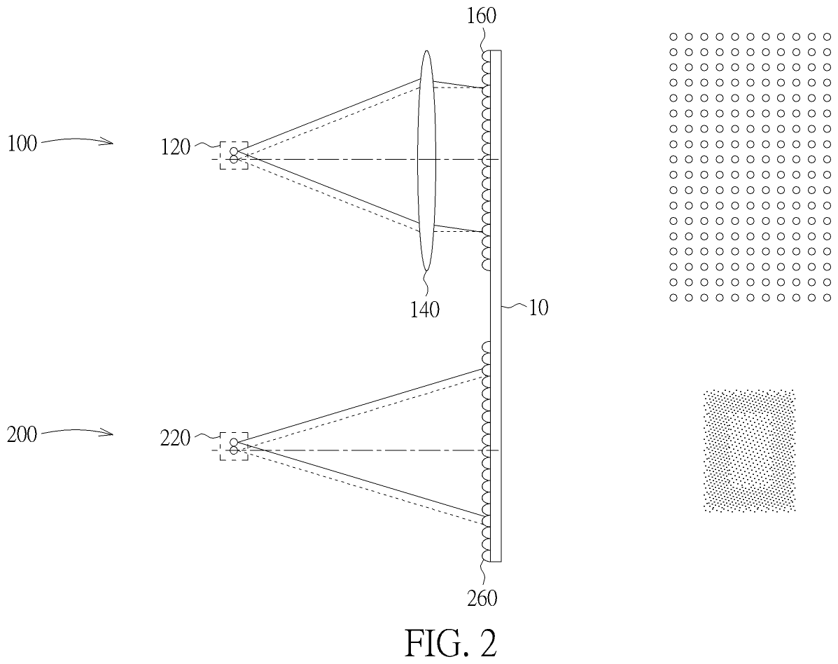

Please refer to FIG. 1, which illustrates a schematic diagram of an optical distance measurement system 10 according to one embodiment of the present invention. As illustrated, the optical distance measurement system 10 comprises a dot pattern projector 100, a flood illuminator 200 and an image capturing device 300. Both of the dot pattern projector 100 and the flood illuminator 200 are configured to project high-power illumination patterns onto an object within a field of view of the image capturing device 300. According to various embodiments of the present invention, the dot pattern projector 100 and the flood illuminator 200 may project different types of illumination patterns sequentially or simultaneously. FIG. 2 illustrates a possible arrangement of the dot pattern projector 100 and the flood illuminator 200. As illustrated, the dot pattern projector 100 (which comprises a light source 120, a collimated lens 140, a diffracting unit 160, and projects a dot illumination pattern) and the flood illuminator 200 (which comprises a light source 220 and a diffracting unit 260, and projects a flood illumination pattern) share a same substrate. The dot pattern projector 100 and the flood illuminator 200 may use separate diffracting units 160 and 260, both of which are disposed on a shared substrate 10. The diffracting unit 160 of the dot pattern projector 100, which may be a microlens array or an optical diffracting unit (DOE), is disposed on the shared substrate 10 that the diffracting unit 260 (which may be a microlens array or an optical diffracting unit (DOE)) of the flood illuminator 200 is disposed on. An advantage of sharing a same substrate and arranging two diffracting unit adjacent to each other is to reduce the complexity of manufacturing process. In this regards, etching or mold reversal of the dot pattern projector 100 and the flood illuminator 200 can be done together, which makes the cost lower, and also reduces the assembly time.

The image capturing device 300 may comprise (but not limited to) a focusing lens, a filter and an image sensor, such as, a complementary metal-oxide semiconductor (CMOS) or a charge-coupled device (CCD) sensor (not shown). The image capturing device 300 is configured to capture images of illumination patterns reflected from the object. According to the images captured by the image sensor 300, depth information regarding the object can be measured.

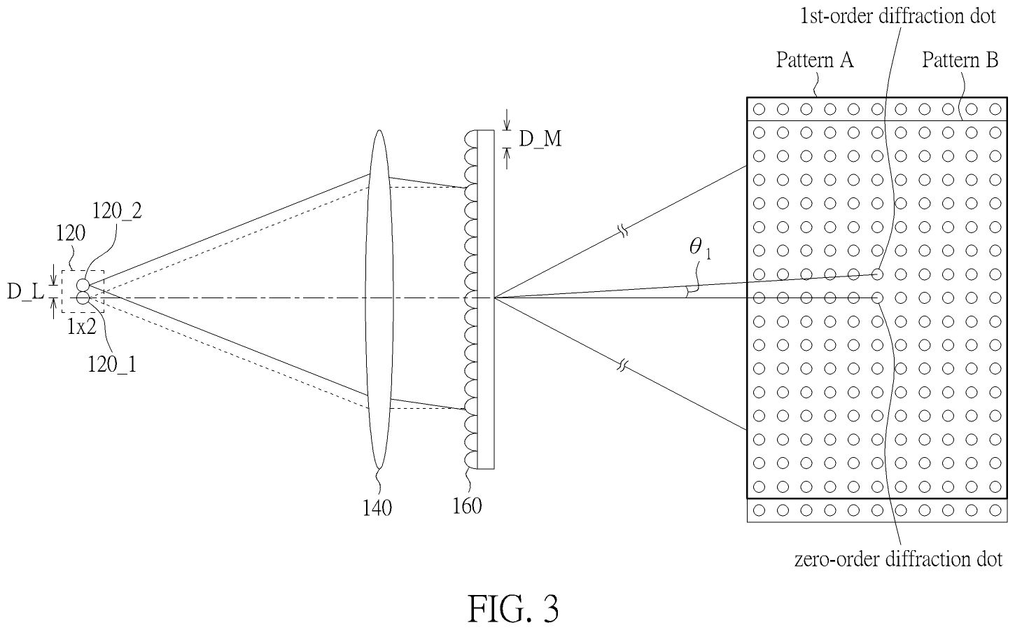

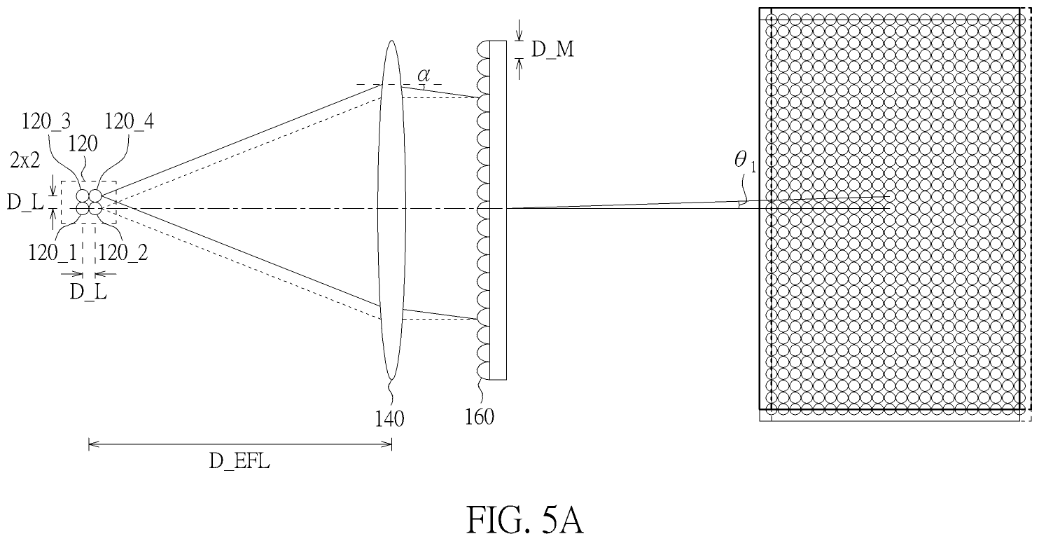

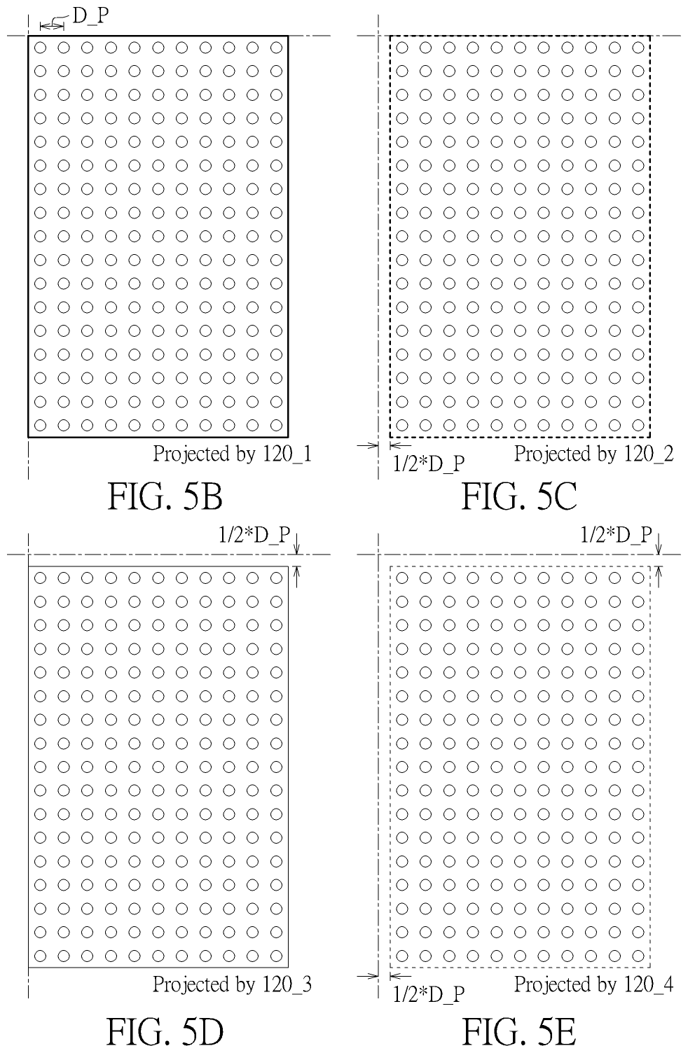

FIG. 3 illustrates a schematic diagram of the dot pattern projector 100 according to one embodiment of the present invention. As illustrated, the dot pattern projector 100 comprises a light source array 120, a lens 140 and a diffracting unit 160. The light source array 120 is arranged to emit light beams, and includes a plurality of light sources 120_1-120_N that are arranged in an array form. According to various embodiment, the light sources 120_1-120_N may be regularly distributed or hexagonally distributed as shown by FIG. 5A. Please note that the number of the light sources 120_1-120_N in the drawings is just for illustrative purpose only. Preferably, the light sources 120_1-120_N could be a vertical-cavity surface-emitting laser (VCSEL) and are equally separated by a pitch D_L.

The lens 140 is arranged to collimate the light beams that are emitted by the light source array 120. Preferably, a distance between of the light source array 120 and an optical center of the lens 140 is identical to an effective focal length D_EFL of the lens 140. Accordingly, with the lens 140, the light beams could be more condensed, thereby allowing dots in the illumination patterns projected by the dot pattern projector 100 to have smaller sizes and higher contrast. The diffracting unit 160 is configured to diffract the light beams thereby to project the illumination patterns having regularly distributed dots as shown by FIG. 2. According to various embodiments, the diffracting unit 160 could a diffraction optical element (DOE) or a microlens array (MLA).

In addition, the flood illuminator 200 may comprises a light source and a diffuser, and use a DOE or a MLA as the diffuser. In one embodiment, once the DOE is used as the diffracting unit 160 in the dot pattern projector 100, a DOE will also be used as the diffuser in the flood illuminator 200. On the other hand, once the MLA is used as the diffracting unit 160 in the dot pattern projector 100, a MLA will also be used as the diffuser in the flood illuminator 200. In the case where the MLA is used as the diffracting unit 160, the MLA 160 comprises a plurality of micro lenses that have a plano-convex shape and a lens pitch between two neighboring unit lenses of the MLA 160 is D_M. In the case where the DOE is used as the diffracting unit 160, a cell pitch between neighboring unit cells of the DOE 160 is D_E. In preferable embodiments, the lens pitch D_M of the MLA 160 or the cell pitch D_E of the DOE 160 could be larger than 10 μm, which is relatively easy for fabrication.

Distribution of dots projected by the light sources 120_1-120_N can be determined according to various parameters. In one embodiment, assuming that a fan-out angle between a dot of zero-order diffraction and a dot of mth-order diffraction of the dot pattern projected by a single light source is Θₘ and a wavelength of the light beam emitted by the light sources is A, a lens pitch of the MLA 160 is D_M, there will be the following relationship between these parameters:

D_M×sin θₘ=mλ;

where m is the diffraction order. In view of this, the fan-out angle Θ₁ between a dot of the zero-order diffraction and a dot of the 1st-order diffraction of the dot pattern will be:

$${θ}_{1} = {sin}^{- 1} ( \frac{λ}{D\_M} ) ;$$

In addition, as shown by FIG. 2, the dot pattern (pattern B) projected by the light source 120_2 that is not positioned at the optical axis of the lens 140 will be shifted in vertical direction compared to the dot pattern (pattern A) projected by the light source 120_1 that is positioned at the optical axis of the lens 140. According to various embodiments, the illumination pattern projected by dot pattern projector 100 is formed by overlapping or interlacing dot patterns projected by different light sources.

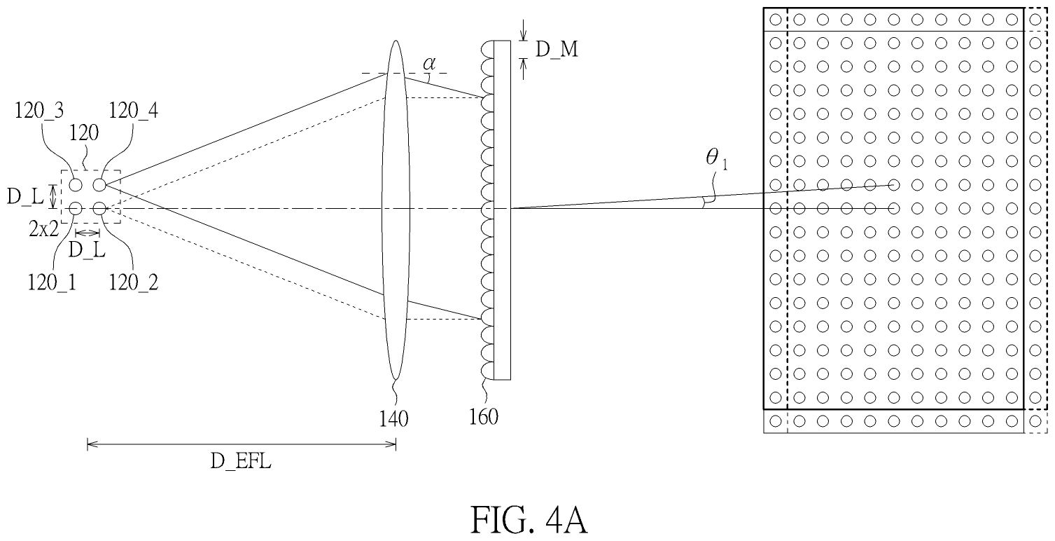

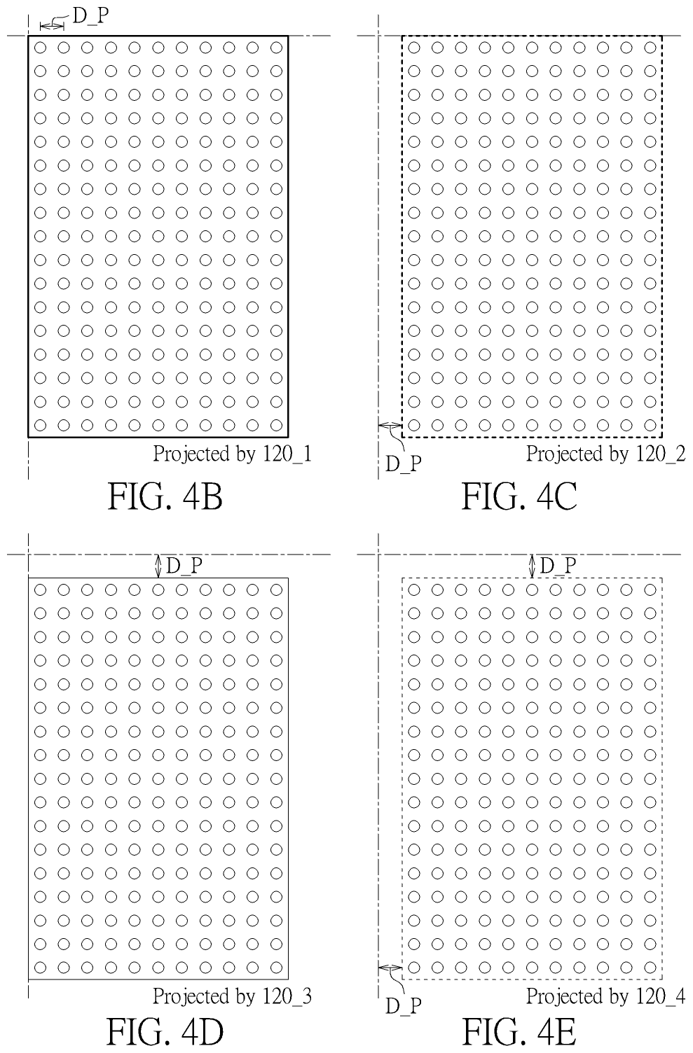

Please refer to FIGS. 4A-4E for understanding how the illumination pattern is formed by overlapping different dot patterns of different light sources according to one embodiment of the present invention. In such embodiment, the light source array 120 is a 2×2 array including light sources 120_1-120_4. FIG. 3B and FIG. 3C illustrate dot patterns produced by the light sources 120_1-120_2 that are positioned at the optical axis of the lens 140, while FIG. 3D and FIG. 3E illustrate dot patterns produced by the light sources 120_3-120_4 that are not positioned at the optical axis of the lens 140. The collimated light beams of light sources 120_3-120_4 will deviate from the optical axis of the lens by a deviation angle α, where the deviation angle α can be determined by:

$$α = {tan}^{- 1} ( \frac{D\_L}{D\_EFL} )$$

(D_L is a pitch between the neighboring light sources; D_EFL is an effective focal length of the lens 140). Therefore, the dot patterns projected by the light sources 120_3-120_4 will be shifted in vertical direction compared to the dot patterns projected by the light sources 120_1-120_2.

In order to exactly overlap the dot patterns, it is necessary to have:

sin α=sin θ₁

That is, the deviation angle α by which the collimated light beams of the light sources deviate from the optical axis needs to be identical to the fan-out angle Θ₁ between the dot of the zero-order diffraction and the dot of the 1st-order diffraction. If the light source pitch D_L, the effective focal length D_EFL and the lens pitch D_M (the diffracting unit 160 is a MLA) or the cell pitch D_E (if the diffracting unit 160 is a DOE) are well controlled to satisfy sin α=sin θ, the dot patterns will be shifted by exactly one dot pitch D_P (i.e., a distance between neighboring dots in the dot pattern) in vertical or horizontal direction compared to each other, thereby forming an overlapping-type illumination pattern.

Please refer to FIGS. 5A-5E for understanding how the illumination pattern is formed by interlacing different dot patterns of different light sources according to one embodiment of the present invention. In such embodiment, the light source array 120 is a 2×2 array including light sources 120_1-120_4. FIG. 4B and FIG. 4C illustrate dot patterns produced by the light sources 120_1-120_2 that are positioned at the optical axis of the lens 140, while FIG. 4D and FIG. 4E illustrate dot patterns produced by the light sources 120_3-120_4 that are not positioned at the optical axis of the lens 140. The collimated light beams of light sources 120_3-120_4 will deviate from the optical axis of the lens by the deviation angle α, where the deviation angle α is also determined by:

$$α = {tan}^{- 1} ( \frac{D\_L}{D\_EFL} )$$

In order to interlacing the dot patterns, it is necessary to have:

N×sin α=sin θ

An interfacing factor N will determine how dot patterns are interlaced. In a case where N is 1, the dot pattern projected by the light sources that are not positioned at the optical axis will be shifted by one dot pitch D_P in vertical or horizontal direction compared to each other, thereby forming the overlapping-type illumination pattern as shown by FIG. 3A. In a case where N is 2, the dot pattern projected by the light sources that are not positioned at the optical axis will be shifted by ½ dot pitch D_P in vertical or horizontal direction compared to each other, thereby forming the interlacing-type illumination pattern as shown by FIG. 4A. In a case where N is 3, the dot pattern projected by the light sources that are not positioned at the optical axis will be shifted by ⅓ dot pitch D_P in vertical or horizontal direction compared to each other, which also forms the interlacing-type illumination pattern.

In view of above, the lens pitch D_M of diffracting unit 160 (if the diffracting unit 160 is a MLA) or the cell pitch D_E of the diffracting unit 160 (if the diffracting unit 160 is a DOE) can determine the fan-out angle θ, which affects dot distributions (e.g., dot density) of the dot pattern projected by a single light source. In addition, the light source pitch D_L and the effective focal length D_EFL of the lens 140 can determine the fan-out angle θ, which affects how a dot pattern are shifted compared to each other.

Assuming that the effective focal length D_EFL is 2 mm and the light source pitch is 30 μm, the lens pitch D_M of diffracting unit 160 (if the diffracting unit 160 is a MLA) or the cell pitch D_E of the diffracting unit 160 can be determined by:

$$N \times sin [ {tan}^{= 1} ( \frac{D\_L}{D\_EFL} ) ] = \frac{λ}{D\_M} or$$

$$N \times sin [ {tan}^{= 1} ( \frac{D\_L}{D\_EFL} ) ] = \frac{λ}{D\_E}$$

Therefore, the lens pitch D_M or the cell pitch D_E of diffracting unit 160 will be around 62.7 μm when N=1 (i.e., the overlapping-type) or 31.3 μm when N=2 (i.e., the interlacing-type). Furthermore, to implement an illumination pattern covering a field of interest (FOI): 60° (H) by 40° (V), dimensions of the illumination pattern can be determined by:

D_M×sin(θₘ_{_{H}})=m_{H}×λ; and

D_M×sin(θₘ_{_{V}})=m_{V}×λ;

where θ_{mH}=(60/2) and θₘᵥ=(40/2). Therefore, in the overlapping-type (N=1), the diffraction order in the horizontal direction m_{H} will be ±33, and the diffraction order in the vertical direction my will be ±22. In in the interlaced-type (N=2), the diffraction order in the horizontal direction m_{H} will be ±16, and the diffraction order in the vertical direction m_{V} will be ±11. Accordingly, a total number of dots in the illumination pattern can be determined by:

N²×(2|m_{H}|+1)×(2|m_{V}|+1)

In the case where N=1, m_{H}=±33 and m_{V}=±22, the total number of dots will be around 3015, while in the case where N=2, m_{H}=±16 and m_{V}=±11, the total number of dots will be around 3036. In view of this, it is possible to change the lens pitch D_M (or cell pitch D_M) in conjunction with the interlacing factor “N” to render similar number of dots in a given FOI. This significantly improves flexibility of design and fabrication of the diffracting unit 160.

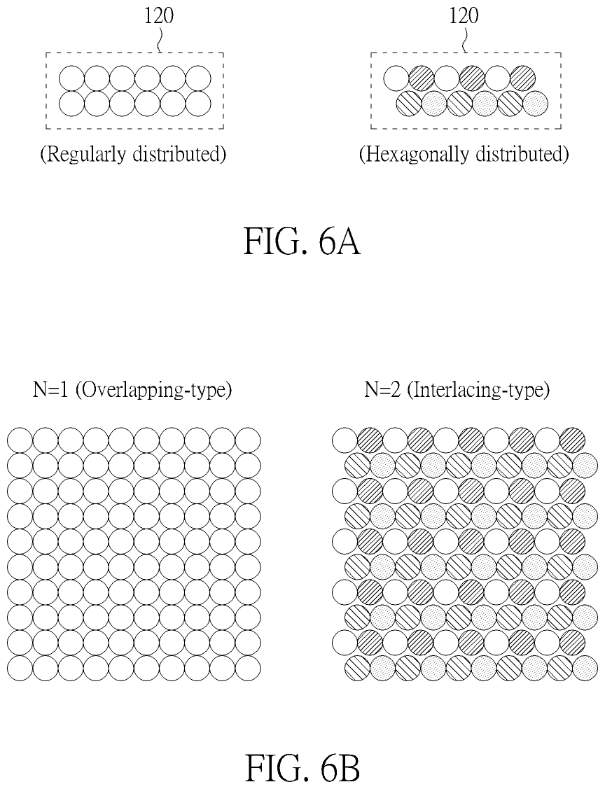

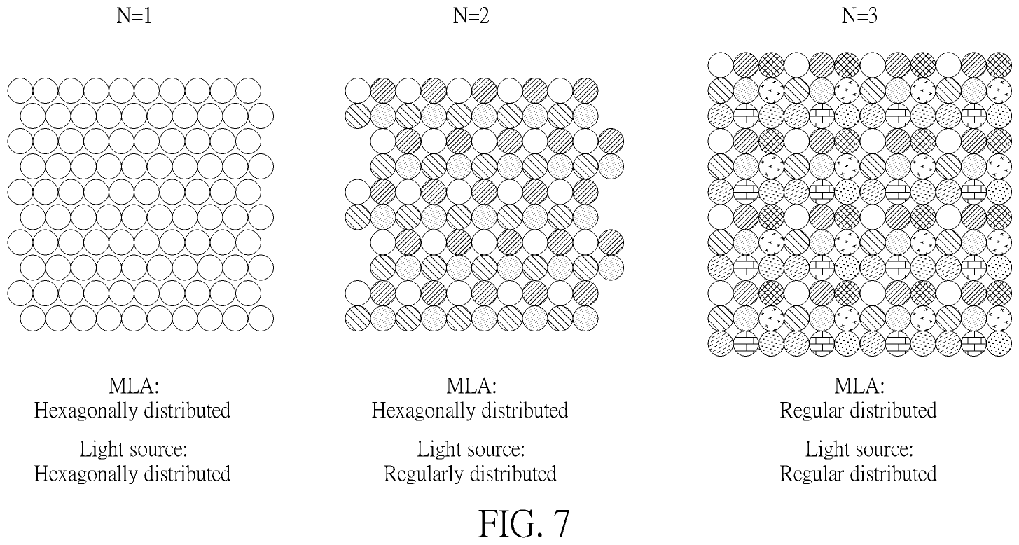

FIG. 6A and FIG. 6B illustrate arrangements of different light source arrays 120 and their corresponding illumination patterns. As illustrated by drawing, distributions of dots in the illumination patterns inherits distributions of the light sources in the light source array 120. FIG. 7 illustrates illumination patterns with respect to combinations of different light source arrangements, unit lens arrangements of MLA, and different interlacing types.

In conclusion, embodiments of the present invention provide a dot pattern projector for use in a three-dimensional optical distance measurement system. The dot pattern projector of the present invention can be used in conjunction with a flood illuminator in an optical distance measurement system, thereby to provide high-power illumination patterns and considerably long distance of projection. Both of a diffuser of the flood illuminator and a diffracting unit of the dot pattern projector can be implemented with same types of optical elements (e.g. both are MLA or DOE), thereby simplifying fabrication of the optical distance measurement system. Moreover, embodiments of the present invention allow dot patterns produced by different light sources of a light source array to be overlapped or interlaced, such that parameters of components of the dot pattern projector could have wide ranges of adjustment. This significantly improves the flexibility of the design and the fabrication of the dot pattern projector.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A dot pattern projector, comprising:
a light source array, including a plurality of light sources that emit light beams;
a lens, configured to collimate the light beams; and
a diffracting unit, configured to diffract the collimated light beams thereby to project an illumination pattern;
wherein the illumination pattern is formed by overlapping multiple dot patterns that are projected by different light sources or interlacing multiple dot patterns that are projected by the light sources.

2. The dot pattern projector of claim 1, wherein each of the light sources is a vertical-cavity surface-emitting laser (VCSEL).

3. The dot pattern projector of claim 1, wherein a light source pitch between two neighbor light sources is regular.

4. The dot pattern projector of claim 1, wherein the light sources are regularly distributed or hexagonally distributed within the light source array.

5. The dot pattern projector of claim 1, wherein the diffracting unit comprises a microlens array (MLA) or a diffractive optical element (DOE).

6. The dot pattern projector of claim 1, a distance between of the light source array and an optical center of the lens is identical to an effective focal length of the lens.

7. The dot pattern projector of claim 1, wherein if a wavelength of the light beams emitted by the light sources is A, a fan-out angle between a dot of the zero-order diffraction and a dot of the mth-order diffraction in the dot pattern projected by a light source is θₘ, and a cell pitch or a lens pitch of the diffracting unit is D_M, the above-mentioned parameters will have a relationship of: D_M×sin θₘ=mλ.

8. The pattern projection apparatus of claim 1, wherein if a light source pitch between two neighboring light sources is D_L, an effective focal length of the lens is D_EFL, a deviation angle between an optical axis of the lens and a collimated light beam of a light source that is not positioned at the optical axis is a, the above-mentioned parameters have a relationship of:
$$α = {tan}^{- 1} ( \frac{D\_L}{D\_EFL} ) .$$

9. The pattern projection apparatus of claim 1, wherein if the illumination pattern is formed by overlapping the dot patterns projected by different light sources, a deviation angle between an optical axis of the lens and a collimated light beam of a light source that is not positioned at the optical axis is α, and a fan-out angle between a dot of zero-order diffraction and a dot of 1st-order diffraction in the dot pattern projected by a light source is θ₁, the above-mentioned parameters have a relationship of: sin α=sin θ₁.

10. The pattern projection apparatus of claim 1, wherein if the illumination pattern is formed by interlacing the dot patterns projected by different light sources, a deviation angle between an optical axis of the lens and a collimated light beam of a light source that is not positioned at the optical axis is α and a fan-out angle between a dot of zero-order diffraction and a dot of 1st-order diffraction in the dot pattern projected by a light source is θ₁, the above-mentioned parameters have a relationship of: N×sin α=sin θ₁.

11. An optical distance measurement system, comprising:
a flood illuminator, including at least one light source and a diffuser, configured to project a first illumination pattern;
a dot pattern projector, configured to project a second illumination pattern, comprising:
a light source array including a plurality of light sources that emit light beams;
a lens, configured to collimate the light beams; and
a diffracting unit, configured to diffract the collimated light beams thereby to project an illumination pattern, wherein the illumination pattern is formed by overlapping multiple dot patterns that are projected by different light sources or interlacing multiple dot patterns that are projected by different light sources; and
an image capturing device, configured to capture images of illumination pattern reflected from an object.

12. The optical distance measurement system of claim 11, wherein both of the diffuser and the diffracting unit comprise microlens arrays.

13. The optical distance measurement system of claim 11, wherein both of the diffuser and the diffracting unit comprise diffractive optical elements.
